(19) United States
(12) Patent Application Publication
(10) Pub. No.: US 2006/0127780 A1
(43) Pub. Date: Jun. 15, 2006

(54) Forming a capping layer for a EUV mask and structures formed thereby

(76) Inventors: Manish Chandhok, Beaverton, OR (US); Ming Fang, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/014,542

(22) Filed: Dec. 15, 2004

(51) Int. Cl. G03C 5/00; G21K 5/00; G03F 1/00

(52) U.S. Cl. 430/5; 378/35; 430/322

(57) ABSTRACT

Methods of forming a microelectronic structure are described. Embodiments of those methods include providing a substrate comprising a first reflective layer disposed on a second reflective layer, wherein the thickness of the first reflective layer and the thickness of the second reflective layer are less than about 100 angstroms, and forming a ruthenium oxide layer on the substrate, wherein the ruthenium oxide layer is about 50 angstroms or less.

### BACK GROUND OF THE INVENTION

During the manufacture of microelectronic devices, many layers may be fabricated on a substrate, and a reticle or photomask may be required for each layer that may be formed, or patterned on a substrate, such as a silicon wafer

As the dimensions of patterned layers on microelectronic devices have become increasingly small, radiation sources such as deep ultraviolet (248 nm or 193 nm), vacuum ultraviolet (157 nm) and extreme ultraviolet (EUV) (13.4 nm) have been are being used or are being considered. EUV lithography, which uses a source at 13.5 nm wavelength, is a promising technology for 0.3 micron and below microelectronic device fabrication, for example. Since the absorption at that wavelength is very strong in most materials, EUV lithography may employ reflective mask reticles, rather than through-the-mask reticles used in longer wavelength lithography.

### BRIEF DESCRIPTION OF THE DRAWINGS

While the specification concludes with claims particularly pointing out and distinctly claiming certain embodiments of the present invention, the advantages of this invention can be more readily ascertained from the following description of the invention when read in conjunction with the accompanying drawings in which:

FIGS. 1a-1b methods of forming structures according to an embodiment of the present invention.

FIGS. 2a-2c represent methods of forming structures according to another embodiment of the present invention.

FIG. 3 represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming and utilizing a microelectronic structure, such as a reticle capping layer structure, are described. Those methods may comprise providing a substrate comprising a first reflective layer disposed on a second reflective layer, wherein the thickness of the first reflective layer and the thickness of the second reflective layer are less than about 100 angstroms, and forming a ruthenium oxide layer on the substrate, wherein the ruthenium oxide layer is about fifty angstroms or less.

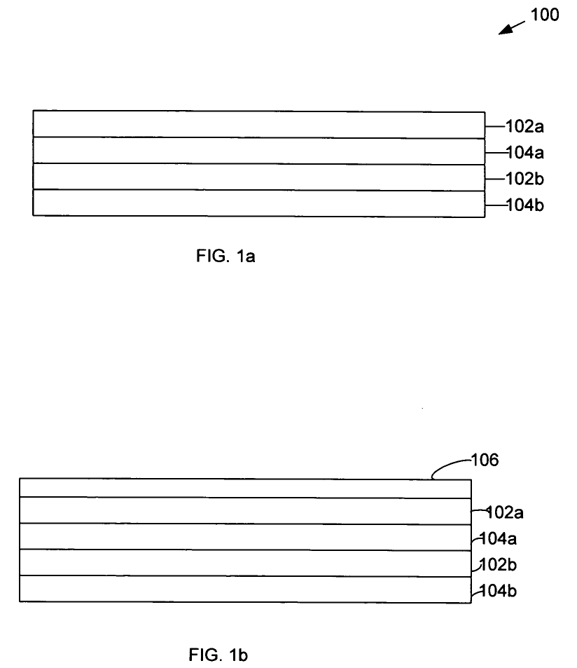

FIGS. 1a-1b illustrate an embodiment of a method of forming a microelectronic structure, such as a reticle capping layer structure, for example. FIG. 1a illustrates a substrate 100. In one embodiment, the substrate 100 may comprise a reflective substrate 100. The reflective substrate 100 may comprise alternating thin layers of a first reflective layer 102a, 102b and a second reflective layer 104a, 104b. In one embodiment, the reflective substrate 100 may comprise a reflective mask or reticle, such as a mask or reticle that may reflect radiation in the extreme ultraviolet (EUV) region (i.e., less than about 15 nm), as is well known in the art, for example during a EUV lithographic process.

In one embodiment, the first reflective layer 102a, 102b may comprise silicon, and the second reflective layer 104a, 104b may comprise molybdenum. In one embodiment, the first reflective layer 102a, 102b may comprise a thickness of less than about 100 angstroms. In another embodiment, the first reflective layer 102a, 102b may comprise a thickness from about 20 to about 80 angstroms. In one embodiment, the second reflective layer 104a, 104b may comprise a thickness of less than about 100 angstroms. In another embodiment, the second reflective layer 104a, 104b may comprise a thickness from about 20 to about 80 angstroms. In one embodiment, the substrate 100 may comprise a combined total of approximately 20-100 alternating layers of the first reflective layer 104a, 104b and the second reflective layer 102a, 102b, as is known in the art.

A ruthenium oxide layer 106 may be formed on the reflective substrate 100, and may comprise a reticle capping layer structure, as is well known in the art (FIG. 1b). In one embodiment, the ruthenium oxide layer 106 may serve to protect the reflective substrate 100 from oxidation, for example. The ruthenium oxide layer 106 may comprise a thickness of about fifty angstroms or less, in one embodiment. In one embodiment, the ruthenium oxide layer 106 may be formed by RF sputtering utilizing an oxygen and argon gas mixture. The concentrations of the oxygen and argon gases will depend on the particular application. In general, the ruthenium oxide layer 106 may be formed by any deposition and/or formation method that may form a thin ruthenium oxide layer 106. In some embodiments, the ruthenium oxide layer 106 may comprise a substantially amorphous ruthenium oxide layer 106.

The ruthenium oxide layer 106 may reflect radiation in the EUV region, such as a wavelength comprising about 15 nm or less in one embodiment. In one embodiment, the ruthenium oxide layer 106 may reflect (i.e., comprise a reflectivity) greater than about 70 percent of incident EUV radiation that may be directed toward it, such as in a EUV lithographic process as is well known in the art. In another embodiment, the substrate 100 with the ruthenium oxide layer 106 disposed on top of the substrate 100 as a capping layer, for example, may reflect greater than about 70 percent of incident EUV radiation that may be directed toward it.

In one embodiment, the ruthenium oxide layer 106 and/or the reflective substrate 100 with the ruthenium oxide layer 106 disposed as a capping layer on it may comprise a lifetime of about 1 percent in about 30,000 hours of use, i.e., the ruthenium oxide layer 106 may lose about 1 percent of its reflectivity of EUV radiation in about 30,000 hours of use during a typical EUV process, depending upon the particular process parameters. In one embodiment, the substrate 100 comprising the ruthenium oxide layer 106 disposed as a capping layer on the substrate 100 may comprise a lifetime of about 1 percent in about 30,000 hours.

Because the ruthenium oxide layer 106 of FIG. 1b may, in some embodiments, comprise a sunstantially amorphous ruthenium layer 106 and thus may lack an appreciable amount of grain boundaries, the ruthenium oxide layer 106 may exhibit little to no oxidation in general, thus enabling the enhanced lifetime of the ruthenium oxide layer 106 and/or the ruthenium oxide 106 layer disposed on reflective substrate 100.

The ruthenium oxide layer 106 may catalyze a reaction between oxygen and carbon that may be present in a chamber and/or present on the reflective substrate 100, for example during a EUV lithographic process as is well known in the art. The ruthenium oxide layer 106 may catalyze a reaction that may comprise oxygen reacting with carbon and/or carbon monoxide to form carbon dioxide, for example. Thus, by catalyzing the formation of carbon dioxide, the ruthenium oxide layer 106 disposed on the substrate 100 may prevent oxidation of the reflective substrate 100 by substantially removing available oxygen from the lithographic chamber.

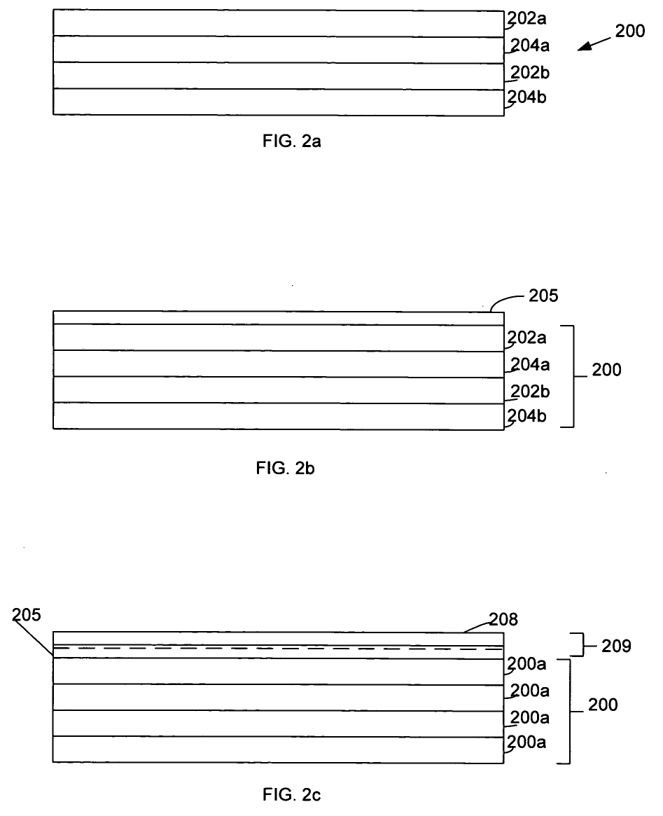

FIGS. 2a-2c depict another embodiment of a method of forming a microelectronic structure, such as a reticle capping layer structure, for example. FIG. 2a illustrates a substrate 200. In one embodiment, the substrate 200 may comprise a reflective substrate 200, similar to the reflective substrate 100 of FIG. 1a, for example. The reflective substrate 200 may comprise alternating thin layers of a first reflective layer 202a, 202b and a second reflective layer 204a, 204b. An amorphous ruthenium layer 205 may be formed on the reflective substrate 200 (FIG. 2b). The amorphous ruthenium layer 205 may comprise little to no grain boundaries, as is well known in the art. In one embodiment, the amorphous ruthenium layer 205 may comprise a thickness of about thirty angstroms or less. In one embodiment, the amorphous ruthenium layer 205 may be formed by RF sputtering utilizing an argon gas mixture and a ruthenium target. In general, the amorphous ruthenium layer 205 may be formed by any formation method that may form a thin amorphous ruthenium layer 205, as is well known in the art.

In one embodiment, an oxygen containing ruthenium layer 208 may be formed on and/or within the amorphous ruthenium layer 205 (FIG. 2c). The oxygen containing Ru layer 208 may be formed by adsorption of oxygen on and/or within the amorphous ruthenium layer 205. In one embodiment, the oxygen containing ruthenium layer 208 may be formed by placing the amorphous ruthenium layer 205 in an atmosphere of oxygen, at a pressure of greater than about 1 bar. In one embodiment, the percentage of oxygen contained within the oxygen containing ruthenium layer 208 may range from 1-2 percent to about 90 percent, depending upon the application. In one embodiment, the oxygen containing ruthenium layer 208 may comprise a thickness of about 10 angstroms or less, and may be substantially free of a ruthenium oxide.

The amorphous ruthenium layer 205 with the oxygen containing ruthenium layer 208 adsorbed on and/or in it may comprise a reticle capping layer structure 209, that may serve to protect the reflective substrate 200 from oxidation, for example, since in one embodiment, the adsorbed oxygen containing ruthenium layer 208 may prevent oxidation of the underlying amorphous ruthenium layer 205 and may prevent the oxidation of the reflective substrate 200, as is well known in the art.

The reticle capping layer structure 209 may reflect radiation in the EUV region, such as a wavelength comprising about 15 nm or less in one embodiment. In one embodiment, the capping layer 209 and/or the capping layer disposed on the substrate 200 may reflect greater than about 70 percent of EUV radiation that may be directed toward the capping layer 209 and/or the capping layer 209 disposed on the substrate 200, such as in a EUV lithographic process as is well known in the art. In one embodiment, the capping layer 209 and/or the reflective substrate 200 with the capping layer 209 disposed on it may comprise a lifetime of about 1 percent in about 30,000 hours, i.e., the capping layer 209 and/or reflective substrate 200 with the capping layer disposed on it may lose about 1 percent of reflectivity of EUV radiation in about 30,000 hours.

The amorphous ruthenium layer 205 and/or capping layer 209 may catalyze a reaction between oxygen and carbon that may be present in a chamber and/or present on the reflective substrate 200, for example during a EUV lithographic process as is well known in the art. The catalyzed reaction may comprise oxygen reacting with carbon and/or carbon monoxide to form carbon dioxide, for example. Thus, by catalyzing the formation of carbon dioxide, the amorphous ruthenium layer 205 and/or capping layer 209 may prevent oxidation of the reflective substrate 200 by substantially removing available oxygen from the lithographic chamber.

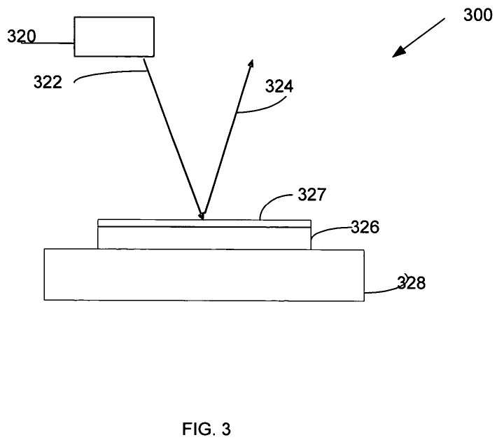

FIG. 3 is a diagram illustrating an exemplary system capable of being operated with methods for fabricating a microelectronic structure, such as the reticle capping layer structure 209 of FIG. 2c, for example. It will be understood that the present embodiment is but one of many possible systems in which a reticle capping layer structure according to the various embodiments of the present invention may be used.

In the system 300, a substrate 326, that in one embodiment may comprise a reflective substrate, such as but not limited to a EUV mask, may be provided. The substrate 326 may comprise a reticle capping layer structure 327, similar to the reticle capping layer structures 106 and 209 of FIG. 1b and FIG. 2c respectively, for example. The substrate 326 may further comprise a reticle holder 328, as is well known in the art. A radiation source 320 may be provided. The source 320 may comprise a EUV source. The EUV source may comprise any radiation source that may comprise a wavelength below about 15 nm. In one embodiment, the wavelength may comprise between about 12-14 nm, and may comprise a laser-induced and/or electrical discharge gas plasma device, for example.

In one embodiment, incident radiation 322, which in one embodiment may be EUV radiation, (i.e. comprising a wavelength between about 12 to about 14 nm), may generated from the radiation source 320, and may further be directing onto the reticle capping layer structure 327 and on the substrate 326. Reflected radiation 324 may comprise above about 70 percent of the incident radiation 322 that may be reflected off the substrate 326 and capping layer structure 327.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that various microelectronic structures, such as reticle capping layer structures, are well known in the art. Therefore, the Figures provided herein illustrate only portions of an exemplary microelectronic structure that pertains to the practice of the present invention. Thus the present invention is not limited to the structures described herein.

What is claimed is:

1. A method of forming a structure comprising;
providing a substrate comprising a first reflective layer disposed on a second reflective layer, wherein the thickness of the first reflective layer and the thickness of the second reflective layer are less than about 100 angstroms; and
forming a ruthenium oxide layer on the substrate, wherein the ruthenium oxide layer is about 50 angstroms or less.

2. The method of claim 1 further comprising wherein the ruthenium oxide layer is formed by RF sputtering in a gas mixture comprising argon and oxygen.

3. The method of claim 1 further comprising directing incident EUV radiation onto the ruthenium oxide layer, wherein the structure reflects above about 70 percent of the incident EUV radiation.

4. The method of claim 3 further comprising wherein the structure comprises a decrease in reflectivity of about 1 percent in about 30,000 hours.

5. The method of claim 3 further comprising wherein the ruthenium oxide layer catalyzes the reaction of carbon with oxygen to form carbon dioxide to substantially eliminate oxidation of the substrate.

6. The method of claim 1 further comprising wherein the first reflective layer comprises silicon.

7. The method of claim 1 further comprising wherein the second reflective layer comprises molybdenum.

8. A method comprising:
providing a substrate comprising a first reflective layer disposed on a second reflective layer, wherein the thickness of the first reflective layer and the thickness of the second reflective layer are less than about 100 angstroms;
forming an amorphous ruthenium layer on the substrate, wherein the amorphous ruthenium layer is about 30 angstroms or less; and
forming an oxygen containing ruthenium layer on the amorphous ruthenium layer.

9. The method of claim 8 wherein forming the oxygen containing ruthenium layer on the amorphous ruthenium layer comprises adsorbing oxygen on and within the amorphous ruthenium layer.

10. The method of claim 9 wherein adsorbing oxygen on and within the amorphous ruthenium layer comprises placing the amorphous ruthenium layer in an oxygen bath at a pressure above about 1 bar.

11. The method of claim 8 further comprising wherein the oxygen containing ruthenium layer comprises a thickness of about 10 angstroms or less.

12. The method of claim 8 further comprising wherein the amorphous ruthenium layer comprises a thickness of about 35 angstroms or less.

13. The method of claim 8 wherein forming the amorphous ruthenium layer on the substrate, wherein the amorphous ruthenium layer is about 50 angstroms or less; and forming an oxygen containing ruthenium layer on the amorphous ruthenium layer comprises forming a reticle capping layer on the substrate by:
forming an amorphous ruthenium layer comprising a thickness of less than about 50 angstroms on the substrate, and
forming an oxygen containing ruthenium layer on the amorphous ruthenium layer comprising a thickness of about 10 angstroms or less.

14. The method of claim 13 further comprising directing incident EUV radiation onto the reticle capping layer, wherein the reticle capping layer reflects above about 70 percent of the incident EUV radiation.

15. The method of claim 14 further comprising wherein the reticle capping layer decreases in reflectivity by about 1 percent in about 30,000 hours.

16. A structure comprising:
a substrate comprising a first reflective layer disposed on a second reflective layer, wherein the thickness of the first reflective layer and the thickness of the second reflective layer are less than about 100 angstroms; and
a ruthenium oxide layer disposed on the substrate, wherein the ruthenium oxide layer comprises a thickness of less than about 50 angstroms.

17. The structure of claim 16 wherein the structure is capable of reflecting above about 70 percent of incident EUV radiation.

18. The structure of claim 16 wherein the first reflective layer comprises silicon.

19. The structure of claim 16 wherein the second reflective layer comprises molybdenum.

20. The structure of claim 16 wherein the ruthenium oxide layer comprises a thickness of about 20 angstroms.

21. The structure of claim 16 wherein the structure comprises a reflectivity loss of about 1 percent in about 30,000 hours.

22. A structure comprising:
a substrate comprising a first reflective layer disposed on a second reflective layer, wherein the thickness of the first reflective layer and the thickness of the second reflective layer are less than about 100 angstroms;
a reticle capping layer disposed on the substrate, wherein the reticle capping layer comprises an oxygen containing ruthenium layer disposed on an amorphous ruthenium layer.

23. The structure of claim 22 wherein the amorphous ruthenium layer comprises a thickness of about 15 angstroms and the oxygen containing ruthenium layer comprises a thickness of about 10 angstroms.

24. The structure of claim 22 wherein the reticle capping layer is capable of reflecting above about 70 percent of incident EUV radiation.

25. A system comprising:
a EUV source capable of directing EUV radiation on a reflective substrate;
a ruthenium oxide layer disposed on the reflective substrate, wherein the ruthenium oxide layer comprises a thickness of less than about 50 angstroms, and wherein at least about 70 percent of the EUV radiation is capable of being reflected from the ruthenium oxide layer.

26. The system of claim 25 wherein the reflective substrate comprises a first reflective layer disposed on a second reflective layer, wherein the thickness of the first reflective layer and the thickness of the second reflective layer are less than about 100 angstroms.

27. The system of claim 25 wherein the first reflective layer comprises silicon.

28. The system of claim 25 wherein the second reflective layer comprises molybdenum.

29. The system of claim 25 wherein the EUV source comprises a wavelength of less than about 15 nm.
